(19) United States
(12) Patent Application Publication
(10) Pub. No.: US 2020/0301220 A1
(43) Pub. Date: Sep. 24, 2020

(54) DISPLAY DEVICE

(71) Applicant: Sharp Kabushiki Kaisha, Osaka (JP)

(72) Inventors: Keiichi INA, Sakai City (JP); Yasuyoshi KAISE, Sakai City (JP)

(21) Appl. No.: 16/819,297

(22) Filed: Mar. 16, 2020

Related U.S. Application Data
(60) Provisional application No. 62/820,891, filed on Mar. 20, 2019.

(51) Int. Cl. G02F 1/1362; H01L 27/12

(52) U.S. Cl. CPC G02F 1/136286; H01L 27/124

(57) ABSTRACT

A display device includes a through-hole passing through a display region, a plurality of signal lines, and a plurality of scanning lines. Each of the plurality of signal lines includes a first straight line portion and a first bypass portion. Each of the plurality of scanning lines is wired in a layer different from a layer of the plurality of signal lines, and includes a second straight line portion and a second bypass portion. The first straight line portion of each signal line and the second bypass portion of each scanning line intersect each other in a plan view, and the first bypass portion of each signal line and the second bypass portion of each scanning line are wired in different regions from each other.

### TECHNICAL FIELD

The present invention relates to a display device.

### BACKGROUND ART

Some electronic devices of today provided with camera functions such as smartphones have a camera lens disposed in a display region in order to secure an area of the display region. In such electronic devices, a through-hole is provided in the display region for mounting the camera lens.

In the display region, wiring lines such as signal lines and scanning lines need to take a bypass route on the periphery of the through-hole. However, when the wiring lines take a bypass route to avoid the through-hole, the area of the display region is reduced by an amount of area of the bypass route taken by the wiring lines.

Thus, for example, JP 2008-257191 A discloses a display device in which the wiring space is saved by making the wiring lines bypass the through-hole in a state of part of the wiring lines being put together. In the stated display device, at a portion where the signal lines and the scanning lines intersect each other in a plan view, the signal lines and the scanning lines are provided in separate layers and then wired, thereby securing the area of the display region.

### SUMMARY OF INVENTION

However, in the display device of JP 2008-257191 A, since the signal lines and the scanning lines intersect each other in a plan view at the portion where the wiring lines are made to take the bypass route, parasitic capacitance is generated between the signal lines and the scanning lines disposed in the separate layers. As a result, there arises a problem that the display quality of the display device may be degraded.

An embodiment of the present invention has been conceived in order to solve the above problem, and an object thereof is to provide a display device able to reduce parasitic capacitance generated between signal lines and scanning lines.

(1) An embodiment of the present invention is a display device that includes a substrate having a display region; a through-hole passing through the display region; a plurality of first wiring lines having a first straight line portion extending linearly along a first direction, and a first bypass portion wired while bypassing the through-hole; and a plurality of second wiring lines wired in a layer different from a layer of the plurality of first wiring lines, and having a second straight line portion extending linearly along a second direction, and a second bypass portion wired while bypassing the through-hole. In the display device, the first straight line portion of the plurality of first wiring lines intersects with the second bypass portion of the plurality of second wiring lines when viewed from a thickness direction of the substrate, and the first bypass portion of the plurality of first wiring lines and the second bypass portion of the plurality of second wiring lines are wired in different regions from each other.

(2) An embodiment of the present invention is a display device configured such that, in addition to the configuration of (1) described above, part of a plurality of the first bypass portions is formed in a layer identical to the layer of the first straight line portion, and the other part thereof is formed in a layer different from the layer of the first straight line portion.

(3) An embodiment of the present invention is a display device configured such that, in addition to the configuration of (2) described above, part of the plurality of first bypass portions is formed in a layer on an upper side relative to the first straight line portion.

(4) An embodiment of the present invention is a display device configured such that, in addition to the configuration of (2) described above, part of the plurality of first bypass portions is formed in a layer on a lower side relative to the first straight line portion.

(5) An embodiment of the present invention is a display device configured such that, in addition to the configuration of (2) described above, a pitch between the plurality of first bypass portions is shorter than a pitch between the plurality of first straight line portions.

(6) An embodiment of the present invention is a display device configured such that, in addition to any one of the configurations of (1) to (5) described above, the first wiring line is a signal line, the second wiring line is a scanning line, and the plurality of first wiring lines are formed in a layer on an upper side relative to the plurality of second wiring lines.

According to aspects of the present invention, it is possible to reduce parasitic capacitance generated between the signal line and the scanning line, and enhance display quality of the display device.

### BRIEF DESCRIPTION OF DRAWINGS

FIG. 1 is a schematic diagram of a display device according to a first embodiment of the present invention.

FIG. 2 is an enlarged view of a periphery of a through-hole in FIG. 1.

FIG. 3 is a plan view illustrating a wiring line structure in the periphery of the through-hole in FIG. 2.

FIG. 4 is an enlarged view of a portion where a signal line and a scanning line in FIG. 3 intersect each other.

FIG. 5 is a schematic diagram illustrating a cross section taken along a V-V line in FIG. 3.

FIG. 6 is a schematic diagram illustrating a cross section taken along a VI-VI line in FIG. 3.

FIG. 7 is a diagram according to a second embodiment of the present invention corresponding to the diagram in FIG. 5.

### DESCRIPTION OF EMBODIMENTS

### First Embodiment

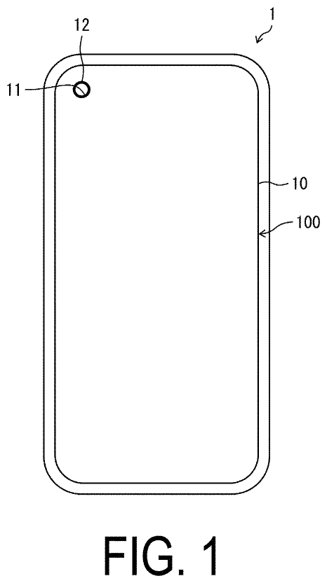

A first embodiment of the present invention will be described hereinafter with reference to FIGS. 1 to 6.

### Schematic Configuration of Display Device

FIG. 1 is a schematic diagram of a display device 1 according to the first embodiment. As illustrated in FIG. 1, the display device 1 has a rectangular outline, for example. The display device 1 includes a color filter substrate 100 and an array substrate disposed opposing each other at a predetermined space, and a liquid crystal layer encapsulated between the above pair of substrates. The display device 1 is used as a liquid crystal display (LCD) of a smartphone, for example. In addition, the display device 1 can also be used in a notebook PC in which the display device 1 functions as a display portion of the PC, for example.

A display region 10 of the display device 1 is disposed on a surface of the color filter substrate 100 (substrate) (the front side of FIG. 1). In the display region 10, a through-hole 11 having a circular shape is formed passing through the display region 10. The through-hole 11 functions as a see through hole (STH) configured to transmit external light. A camera or the like is disposed on a rear face side (rear face side of FIG. 1) of the through-hole 11 of the color filter substrate 100.

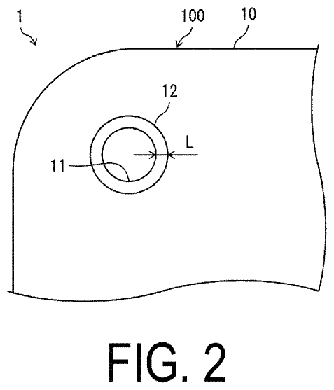

FIG. 2 is an enlarged view of the periphery of the through-hole 11. As illustrated in FIG. 2, a hole frame portion 12 having an annular shape is formed on an outer circumference portion of the through-hole 11. The hole frame portion 12 has a light-blocking property.

The array substrate has a configuration in which, for example, a thin film transistor (TFT) and the like are formed on a surface of a glass substrate on the color filter substrate 100 side. A plurality of signal lines SL (first wiring lines) and a plurality of scanning lines GL (second wiring lines) to be explained later are provided on the array substrate. Note that, in the location where the through-hole 11 is disposed, the glass substrate is present, but the TFT, the signal line SL, the scanning line GL, and the like are not disposed.

The color filter substrate 100 has a configuration in which, for example, a plurality of color filters (CFs), a black matrix, and the like are disposed on a surface of the glass substrate on the array substrate side. The color filters are filters configured to transmit different colors of light, such as red, green, blue, and the like. In the location where the through-hole 11 is disposed, the glass substrate is present, but the members such as a black matrix having a light-blocking property and the like are removed.

### Wiring Line Structure

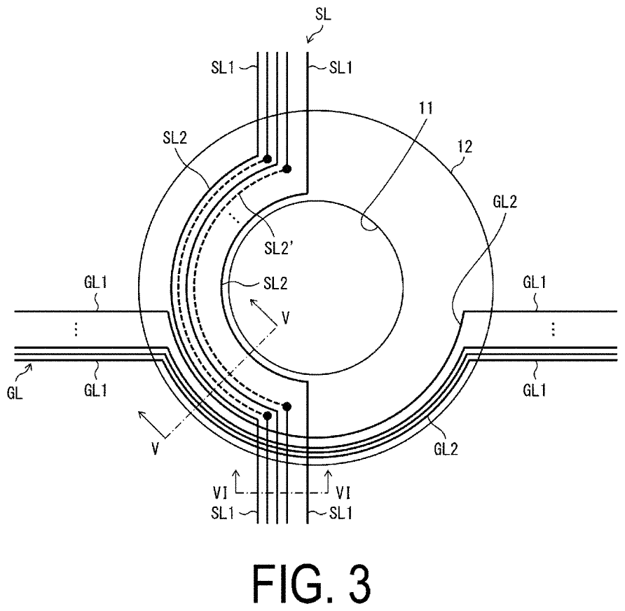

FIG. 3 is a diagram illustrating a wiring line structure in the periphery of the through-hole 11. As illustrated in FIG. 3, the plurality of signal lines SL (first wiring lines) extending in a longitudinal direction (first direction) and the plurality of scanning lines GL (gate lines) extending in a lateral direction (second direction) are formed in the layers on the upper side (the front side of FIG. 1) of the array substrate. Description of the wiring line structure other than the wiring line structure in the periphery of the through-hole 11 will be omitted.

Each of the plurality of signal lines SL is a signal line SL that includes a first straight line portion SL1 extending linearly along the longitudinal direction (an up and down direction in FIG. 3) and a first bypass portion SL2 wired while taking a semicircular arc-shaped bypass route on the left side of the outer circumference portion of the through-hole 11, or a signal line SL that includes the first straight line portion SL1 extending linearly along the longitudinal direction and a first bypass portion SL2′ wired while taking a semicircular arc-shaped bypass route on the left side of the outer circumference portion of the through-hole 11. The first bypass portion SL2 and the first bypass portion SL2′ are alternately wired in a plan view. The first straight line portion SL1 and the first bypass portion SL2′ are formed in different layers, and are connected to each other at a black circle portion in FIG. 3.

Each of the plurality of scanning lines GL includes a second straight line portion GL1 extending linearly along the lateral direction (a left and right direction in FIG. 3), and a second bypass portion GL2 wired while taking a semicircular arc-shaped bypass route on the lower side of the outer circumference portion of the through-hole 11.

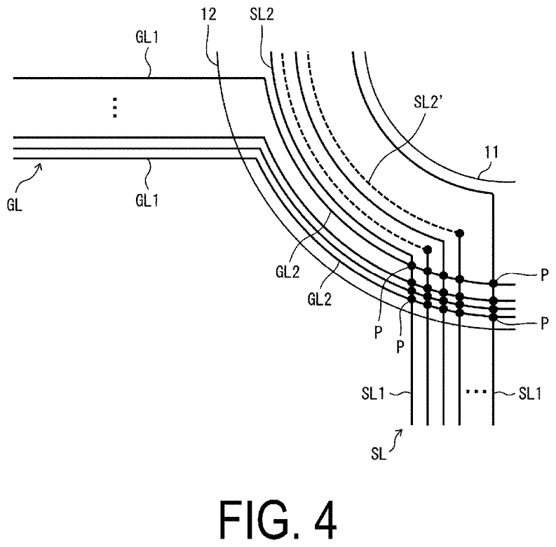

FIG. 4 is an enlarged view of a portion where the plurality of signal lines SL and the plurality of scanning lines GL intersect each other. As illustrated in FIG. 4, the first straight line portion SL1 of the signal line SL and the second bypass portion GL2 of the scanning line GL intersect each other at each of a plurality of points P when viewed from a thickness direction of the color filter substrate 100.

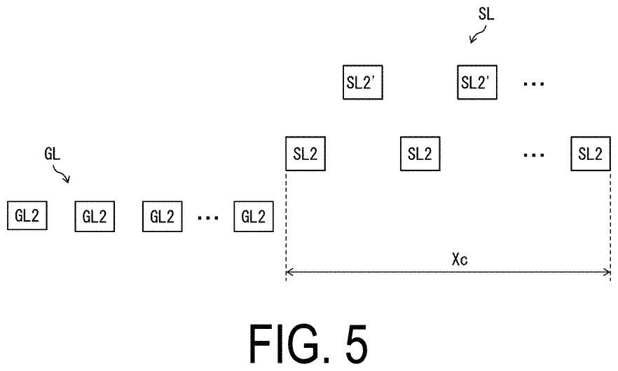

FIG. 5 is a schematic diagram illustrating a cross section taken along a V-V line in FIG. 3. As illustrated in FIG. 5, the plurality of signal lines SL are formed in the layers on the upper side relative to the plurality of scanning lines GL. In addition to the plurality of signal lines SL and the plurality of scanning lines GL, touch panel wiring lines for a touch panel and the like are also present in the display device 1.

The first bypass portions SL2 are formed in the same layer as the first straight line portions SL1. On the other hand, the first bypass portions SL2′ are formed in the layer on the upper side relative to the first straight line portions SL1. In other words, as illustrated in FIG. 5, each of the first bypass portions SL2′ is disposed in the layer on the upper side relative to each of the first bypass portions SL2. In the first embodiment, part of the touch panel wiring lines is used as the first bypass portion SL2′.

Thus, in the first embodiment, each of the first bypass portions SL2 and each of the first bypass portions SL2′ are alternately disposed in a plan view, and each of the first bypass portions SL2 and each of the first bypass portions SL2′ are formed in the separate layers, thereby making it possible to cause a pitch between the first bypass portion SL2 and the first bypass portion SL2′ adjacent to each other in the plan view to be shorter than a pitch between the first straight line portions SL1 and SL1 adjacent to each other. As a result, it is possible to reduce a width L of the hole frame portion 12 illustrated in FIG. 2, and reduce an area of the hole frame portion 12. Specifically, the pitch between the first bypass portion SL2 and first bypass portion SL2′ adjacent to each other in the plan view is shortened to be, for example, approximately half the pitch between the adjacent first straight line portions SL1 and SL1.

In the first embodiment, the first bypass portions SL2 and SL2′, and the second bypass portions GL2 are wired in different regions in the plan view (see FIGS. 3 and 4). To rephrase, the region where each first bypass portion SL2 or SL2′ of each signal line SL is wired and the region where each second bypass portion GL2 of each scanning line GL is wired, are disposed at separate positions when viewed from the thickness direction of the color filter substrate 100 (see FIG. 5). With this, the first bypass portions SL2 and SL2′ of the plurality of signal lines SL and the second bypass portions GL2 of the plurality of scanning lines GL do not have any areas opposing each other when viewed from the thickness direction of the color filter substrate 100, so that the generation of parasitic capacitance between the first bypass portions SL2 and SL2′ of the plurality of signal lines SL and the second bypass portions GL2 of the plurality of scanning lines GL can be suppressed.

Furthermore, as described above, by causing each signal line SL and each scanning line GL to intersect each other only at the point P where each first straight line portion SL1 and each second bypass portion GL2 intersect each other, parasitic capacitance generated between the first straight line portion SL1 of the signal line SL and the second bypass portion GL2 of the scanning line GL can be reduced.

Since the parasitic capacitance generated at the point P is determined in accordance with the standards such as the size and the number of the signal lines SL and the scanning lines GL, it is possible to prevent a situation in which the parasitic capacitance generated between the signal line SL and the scanning line GL varies depending on the locations.

As described above, according to the display device 1 of the first embodiment, the parasitic capacitance generated between the signal lines SL and the scanning lines GL can be reduced and settled. Accordingly, the display quality of the display region 10 can be enhanced.

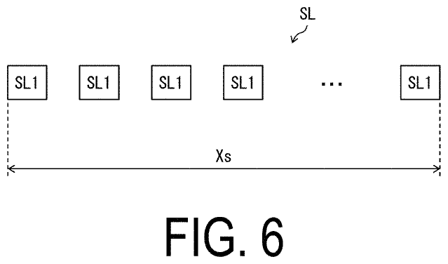

Moreover, the first bypass portions SL2 being approximately half in number of the plurality of signal lines SL are formed in the same layer as the first straight line portions SL1, and the remaining first bypass portions SL2′ being approximately half in number of the plurality of signal lines SL are formed in a layer on the upper side relative to the first straight line portions SL1. Accordingly, it is possible to shorten the pitch between the first bypass portion SL2 and the first bypass portion SL2′ formed in the different layers in comparison with the pitch between the first straight line portions SL1 and SL1 formed in the same layer. This makes it possible to cause a length Xc in a width direction of the overall first bypass portions SL2 and SL2′ illustrated in FIG. 5 to be shorter than a length Xs in the width direction of the overall first straight line portions SL1 illustrated in FIG. 6.

As described above, according to the display device 1 of the first embodiment, it is possible to reduce the width L of the hole frame portion 12, and reduce the area of the hole frame portion 12 (see FIG. 2). Accordingly, the area of the display region 10 can be prevented from being reduced.

### Second Embodiment

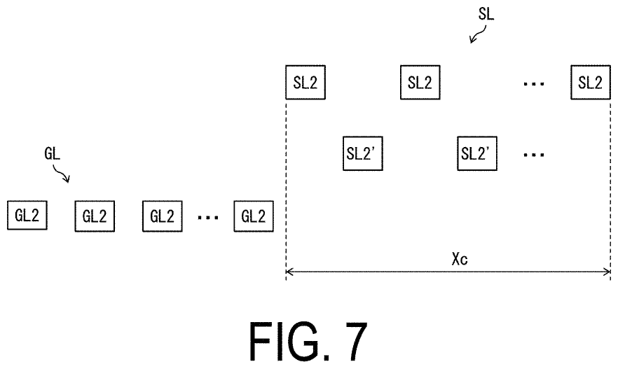

Hereinafter, a display device 1 according to a second embodiment of the present invention will be described with reference to FIG. 7. For the sake of simplicity, members having the same functions as the members described in the foregoing embodiment will be given the same reference signs, and descriptions thereof will not be repeated.

### Wiring Line Structure

FIG. 7 is a schematic diagram illustrating a cross section of a wiring line structure in a periphery of a through-hole 11 according to the second embodiment. As illustrated in FIG. 7, the display device 1 of the second embodiment differs from the display device 1 of the first embodiment in that each of first bypass portions SL2′ is disposed in a layer on the lower side relative to each of first bypass portions SL2.

Similarly to the first embodiment, each of the first bypass portions SL2 is formed in the same layer as first straight line portions SL1. Each of scanning lines GL is formed in a layer on the lower side relative to each of signal lines SL. The region where each of the first bypass portions SL2 and SL2′ of each of the signal lines SL is wired, and the region where each of second bypass portions GL2 of each of the scanning lines GL is wired are disposed at separate positions when viewed from the thickness direction of the color filter substrate 100 (see FIG. 3). The first straight line portions SL1 of each of the signal lines SL and second bypass portions GL2 of the scanning lines GL intersect each other at each of the plurality of points P when viewed from the thickness direction of the color filter substrate 100 (see FIG. 4).

Also in the display device 1 of the second embodiment described above, the first bypass portions SL2 and SL2′ of the signal lines SL and the second bypass portions GL2 of the scanning lines GL are wired in mutually different regions when viewed from the thickness direction of the color filter substrate 100, so that the parasitic capacitance generated between the first bypass portions SL2 and SL2′ and the second bypass portions GL2 can be suppressed.

Furthermore, since each signal line SL and each scanning line GL intersect each other only at the point P where each first straight line portion SL1 and each second bypass portion GL2 intersect each other, the parasitic capacitance generated between the signal line SL and the scanning line GL can be reduced and settled.

In this manner, also in the display device 1 of the second embodiment, by reducing the parasitic capacitance generated between the signal line SL and the scanning line GL, reduction in display quality of the display region 10 can be prevented.

Moreover, the first bypass portions SL2 being approximately half in number of the plurality of signal lines SL are formed in the same layer as the first straight line portions SL1, and the remaining first bypass portions SL2′ being approximately half in number of the plurality of signal lines SL are formed in a layer on the lower side relative to the first straight line portions SL1. Accordingly, it is possible to shorten the pitch between the first bypass portions SL2 and SL2′ formed in the different layers in comparison with the pitch between the first straight line portions SL1 and SL1 formed in the same layer.

This makes it possible to cause a length Xc in the width direction of the overall first bypass portions SL2 and SL2′ of the signal lines SL illustrated in FIG. 7 to be shorter than the length Xs in the width direction of the overall first straight line portions SL1 illustrated in FIG. 6. As a result, it is possible to reduce the width L of the hole frame portion 12, and secure the area of the display region 10 by the decrease in area of the hole frame portion 12 (see FIG. 2).

### OTHER EMBODIMENTS

In the above embodiments, although the through-hole 11 is formed in a circular shape, the through-hole 11 is not limited thereto and may be formed in a rectangular shape, for example. Although the plurality of signal lines SL take a bypasses route on the left side of the through-hole 11, the bypass route is not limited thereto, and the plurality of signal lines SL may take a bypass route on the right side of the through-hole 11. Further, although the through-hole 11 is formed in the upper left corner of the display region 10, the through-hole 11 is not limited thereto and may be formed in a corner of the upper center portion of the display region 10, for example.

In the embodiments described above, the touch panel wiring line is used as the first bypass portion SL2′ of the signal line SL; however, no such limitation is intended. The present invention is also applicable to the display device 1 without the touch panel wiring line.

Further, in the embodiments described above, each of the first bypass portions SL2 and each of the first bypass portions SL2′ are configured to be alternately wired in a plan view; however, no such limitation is intended. For example, a configuration may be adopted in which two first bypass portions SL2′ are wired adjacent to each other in an upper-side layer, two first bypass portions SL2 are wired adjacent to each other in a lower-side layer, and then in sequence, two first bypass portions SL2′ each and two first bypass portions SL2 each are alternately wired in the upper and lower layers.

Furthermore, in the above embodiments, in the location where the through-hole 11 is disposed, although the hole configured to transmit external light is formed in the array substrate, the hole that passes through the glass substrate is not formed; however, no such limitation is intended. For example, the through-hole 11 may pass through the glass substrate constituting the array substrate.

### Supplement

The display device 1 according to a first aspect of the present invention includes the color filter substrate 100 having the display region 10; the through-hole 11 passing through the display region 10; the plurality of first wiring lines (signal lines SL) having the first straight line portion SL1 extending linearly along the first direction (the up and down direction in FIG. 3), and the first bypass portions SL2 and SL2′ wired while bypassing the through-hole 11; and the plurality of second wiring lines (scanning lines GL) wired in a layer different from a layer of the plurality of first wiring lines, and having the second straight line portion GL1 extending linearly along the second direction (the left and right direction in FIG. 3), and the second bypass portion GL2 wired while bypassing the through-hole 11. The first straight line portion SL1 of the plurality of first wiring lines intersects with the second bypass portion GL2 of the plurality of second wiring lines when viewed from the thickness direction of the color filter substrate 100, and the first bypass portions SL2 and SL2′ of the plurality of first wiring lines and the second bypass portion GL2 of the plurality of second wiring lines are wired in different regions from each other.

The display device 1 according to a second aspect of the present invention is such that, in the first aspect, a plurality of the first bypass portions SL2 may be formed in a layer identical to the layer of the first straight line portion SL1, and a plurality of the first bypass portions SL2′ may be formed in a layer different from the layer of the first straight line portion SL1.

The display device 1 according to a third aspect of the present invention is such that, in the second aspect, the plurality of first bypass portions SL2′ may be formed in a layer on the upper side relative to the first straight line portion SL1.

The display device according to a fourth aspect of the present invention is such that, in the second aspect, the plurality of first bypass portions SL2′ may be formed in a layer on the lower side relative to the first straight line portion SL1.

The display device 1 according to a fifth aspect of the present invention is such that, in the second aspect, the pitch between the plurality of first bypass portions SL2 and SL2′ may be shorter than the pitch between a plurality of the first straight line portions SL1.

The display device 1 according to a sixth aspect of the present invention is such that, in any one of the first to fifth aspects, the first wiring line may be the signal line SL, the second wiring line may be the scanning line GL, and the plurality of first wiring lines may be formed in a layer on the upper side relative to the plurality of second wiring lines.

The present invention is not limited to each of the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in each of the embodiments.

1. A display device comprising:
a substrate including a display region;
a through-hole passing through the display region;
a plurality of first wiring lines including a first straight line portion extending linearly along a first direction, and a first bypass portion wired while bypassing the through-hole; and
a plurality of second wiring lines wired in a layer different from a layer of the plurality of first wiring lines, and including a second straight line portion extending linearly along a second direction, and a second bypass portion wired while bypassing the through-hole,
wherein the first straight line portion of the plurality of first wiring lines intersects with the second bypass portion of the plurality of second wiring lines when viewed from a thickness direction of the substrate, and
the first bypass portion of the plurality of first wiring lines and the second bypass portion of the plurality of second wiring lines are wired in different regions from each other.

2. The display device according to claim 1,
wherein part of a plurality of the first bypass portions is formed in a layer identical to a layer of the first straight line portion, and the other part of the plurality of first bypass portions is formed in a layer different from the layer of the first straight line portion.

3. The display device according to claim 2,
wherein part of the plurality of first bypass portions is formed in a layer on an upper side relative to the first straight line portion.

4. The display device according to claim 2,
wherein part of the plurality of first bypass portions is formed in a layer on a lower side relative to the first straight line portion.

5. The display device according to claim 2,
wherein a pitch between the plurality of first bypass portions is shorter than a pitch between a plurality of the first straight line portions.

6. The display device according to claim 1,
wherein the first wiring line is a signal line,
the second wiring line is a scanning line, and
the plurality of first wiring lines are formed in a layer on an upper side relative to the plurality of second wiring lines.
